(19) United States
(12) Patent Application Publication
(10) Pub. No.: US 2024/0120269 A1
(43) Pub. Date: Apr. 11, 2024

(54) POWER MODULE AND MANUFACTURING METHOD THEREOF

(71) Applicants: Hyundai Motor Company, Seoul (KR); Kia Corporation, Seoul (KR)

(72) Inventors: Kyoung Kook HONG, Hwaseong-Si (KR); Su Bin KANG, Seomgnam-Si (KR); Young Seok KIM, Seongnam-Si (KR)

(73) Assignees: Hyundai Motor Company, Seoul (KR); Kia Corporation, Seoul (KR)

(21) Appl. No.: 18/144,637

(22) Filed: May 8, 2023

(30) Foreign Application Priority Data
Oct. 11, 2022 (KR) 10-2022-0129810

(51) Int. Cl. H01L 23/498; H01L 21/48; H01L 23/00; H01L 23/373

(52) U.S. Cl. CPC H01L 23/49861; H01L 21/4839; H01L 23/3735; H01L 24/40; H01L 24/29; H01L 24/32; H01L 24/73; H01L 2224/29139; H01L 2224/32245; H01L 2224/40245; H01L 2224/73263

(57) ABSTRACT

A power module and a manufacturing method include semiconductor chips, an insulating circuit board including an insulating layer and a first metal layer disposed on a first surface of the insulating layer, and lead frames disposed between the semiconductor chips and the insulating circuit board.

### CROSS REFERENCE TO RELATED APPLICATION

The present application claims priority to Korean Patent Application No. 10-2022-0129810, filed Oct. 11, 2022, the entire contents of which is incorporated herein for all purposes by this reference.

### BACKGROUND OF THE PRESENT DISCLOSURE

### Field of the Present Disclosure

The present disclosure relates to a power module and a manufacturing method thereof, which enable efficient dispersion and dissipation of heat generated from a semiconductor chip by a lead frame extending to an arrangement area of the semiconductor chip on a substrate.

### Description of Related Art

Recently, with an increasing interest in the environment, eco-friendly vehicles provided with electric motors as power sources are on the rise. Eco-friendly vehicles are also known as electrified vehicles, and leading examples include electric vehicles (EVs) and hybrid electric vehicles (HEVs).

The electrified vehicles are provided with an inverter for converting direct current (DC) power into alternating current (AC) power when the motor is driven. The inverter is usually composed of one or more power modules including semiconductor chips that perform switching functions.

Meanwhile, in the case of a semiconductor chip of a power module, as a large current of high voltage flows during operation, the semiconductor chip generates heat. For stable operation of the power module, it is necessary to dissipate the heat.

To achieve effective heat dissipation, research and development are in progress on the material or shape of a heat sink that receives heat generated from the semiconductor chip and emits the received heat to the outside thereof, and on a method of connecting the heat sink and a cooling channel.

However, these research and development aim to enable the heat sink to effectively dissipate the heat generated by the semiconductor chip to the outside after receiving the heat, and have little relevance to a heat transfer process from an internal heat source to the heat sink (e.g., from the semiconductor chip to a substrate).

Accordingly, it is necessary to propose a solution for improving the efficiency of heat transfer from the heat source to the heat sink to achieve the effective heat dissipation of the power module.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a power module and a manufacturing method thereof configured for maintaining durability while transferring heat generated from a semiconductor chip to a substrate so that the generated heat is efficiently dispersed and released on the substrate by a lead frame extending to an arrangement area of the semiconductor chip on the substrate.

Objectives of the present disclosure are not limited to the ones mentioned above, and other different objectives not mentioned herein will be clearly understood by those skilled in the art from the following description.

In various aspects of the present disclosures, according to an exemplary embodiment of the present disclosure, there is provided a power module, including: semiconductor chips; an insulating circuit board including an insulating layer and a first metal layer disposed on a first surface of the insulating layer; and lead frames disposed between the semiconductor chips and the insulating circuit board, wherein the lead frames may include: a first lead frame including a first terminal portion and a first extension portion extending from the first terminal portion onto the insulating circuit board to overlap with a predetermined number of the semiconductor chips on a plane; and a second lead frame including a second terminal portion and a second extension portion extending from the second terminal portion onto the insulating circuit board to overlap with remaining semiconductor chips on the plane.

For example, the power module may further include: second metal layers respectively connecting the predetermined number of the semiconductor chips and the first lead frame, and the remaining number of the semiconductor chips and the second lead frame.

For example, a thermal expansion coefficient of each of the second metal layers may be greater than a thermal expansion coefficient of each of the semiconductor chips and smaller than a thermal expansion coefficient of each of the lead frames.

For example, each of the second metal layers may have a larger planar area than each of the semiconductor chips.

For example, each of the lead frames may have a thickness greater than a thickness of the first metal layer.

For example, the lead frames may further include: a third lead frame including a third terminal portion and a third extension portion extending from the third terminal portion to be located between the first lead frame and the second lead frame without overlapping with the semiconductor chips on the plane.

For example, the power module may further include: additional substrates disposed on the lead frames so as not to overlap with the semiconductor chips while overlapping with a portion of an edge portion of the insulating circuit board on the plane.

For example, the power module may further include: a signal pin configured to receive a voltage from outside thereof, wherein the additional substrates may include first additional substrates, each of which is disposed on the first lead frame and the second lead frame, respectively, and configured to transfer a voltage input from the signal pin to at least one of the semiconductor chips.

For example, the additional substrates may include a second additional substrate disposed on at least two of the lead frames, and configured to connect the at least two of the lead frames to be fixed each other.

For example, the additional substrates may be disposed to be vertically symmetrical with the insulating circuit board based on the lead frames.

For example, the insulating circuit board may further include a heat sink plate disposed on a second surface opposite to the first surface of the insulating layer.

In various aspects of the present disclosures, according to an exemplary embodiment of the present disclosure, there is provided a manufacturing method of a power module, the method including: preparing semiconductor chips, an insulating circuit board, lead frames, and second metal layers; stacking and bonding the lead frames on the insulating circuit board; stacking and bonding the second metal layers on some of the lead frames overlapping with the semiconductor chips on a plane; and stacking and bonding the semiconductor chips on the second metal layers.

For example, the stacking and bonding the lead frames may include applying a metal bonding material to a region where the insulating circuit board and the lead frames overlap on the plane, and face-to-face bonding through pressurization and heat treatment.

For example, the preparing may include preparing additional substrates, and may further include stacking and bonding the additional substrates on a region of the lead frames that does not overlap with the semiconductor chips but overlaps with a portion of an edge portion of the insulating circuit on the plane.

For example, the preparing may include preparing connecting portions, and may further include connecting any one of the semiconductor chips and one of the lead frames that do not overlap with the any one of the semiconductor chips on the plane with one of the connecting portions.

As described above, according to the exemplary embodiments of the present disclosure, by increasing the thickness of an entire metal layer disposed under a semiconductor chip by an insulating circuit board and a lead frame, thermal conductivity may be enhanced to improve heat diffusion and dissipation performance, lowering the operating temperature of a power module.

Furthermore, by disposing a second metal layer and an additional substrate on top of the lead frame, it is possible to ensure the durability of the power module by dispersing thermal stress generated by the changes in temperature during process and operation.

Effects obtainable from the present disclosure are not limited to the above-mentioned effects. Other unmentioned effects will be clearly understood by those skilled in the art to which the present disclosure pertains from the following description.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a plan view of a power module according to an exemplary embodiment of the present disclosure;

FIG. 2 is a cross-sectional view of the power module shown in FIG. 1 taken along line A-A′;

FIG. 3 is a view showing stress distributions in the power module following an arrangement of an additional substrate according to the exemplary embodiment of the present disclosure;

FIG. 4A and FIG. 4B are views showing a manufacturing process of the power module according to the exemplary embodiment of the present disclosure; and

FIG. 5 is a view showing effects of the power module according to the exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, embodiments included in the present specification will be described in detail with reference to the accompanying drawings, with the same or similar elements being assigned the same reference numerals regardless of numerals used in the drawings, and overlapping descriptions thereof will be omitted. The suffixes “module” and “part” for the elements used in the following description are provided or mixed in consideration of only the ease of writing the specification, and do not have distinct meanings or roles by themselves. In describing the exemplary embodiments included in the present specification, if it is determined that detailed descriptions of related known technologies may obscure the gist of the exemplary embodiments included in the present specification, the detailed description thereof will be omitted. Furthermore, it should be understood that the accompanying drawings are only for easy understanding of the exemplary embodiments included in the present specification, and the technical idea included in the present specification is not limited by the accompanying drawings, and the present disclosure covers all changes, equivalents and substitutes within the spirit and scope of the present disclosure.

Terms including an ordinal number, such as first, second, etc., may be used to describe various elements, but the elements are not limited by the terms. These terms are used only for distinguishing one element from another.

When an element is referred to as being “connected” to another element, it should be understood that the other element may be directly connected to the other element, but other element(s) may exist in between. On the other hand, when it is said that a certain element is “directly connected” to another element, it should be understood that no other element is present in the middle.

The singular expression includes the plural expression unless the context clearly dictates otherwise.

In the present specification, the terms “comprise”, “include”, or “have” are intended to indicate that there is a feature, number, step, action, element, part, or combination thereof described on the specification, and it is to be understood that the present disclosure does not exclude the possibility of the presence or the addition of one or more other features, numbers, steps, actions, elements, parts, or combinations thereof.

According to an exemplary embodiment of the present disclosure, by increasing the thickness of an entire metal layer disposed between the bottom portion of a semiconductor chip and the top portion of an insulating layer by a lead frame extending to an arrangement area of the semiconductor chip on an insulating circuit board, heat generated from the semiconductor chip may be efficiently transferred to a heat sink plate and durability may be maintained by disposing a second metal layer and an additional substrate on top of the lead frame.

Meanwhile, since the thickness of the heat sink plate disposed on the opposite side of the insulating layer facing the semiconductor chip does not significantly contribute to heat dissipation performance, and rather, as the thickness of the heat sink plate increases, the distance between the semiconductor chip and a cooling portion increases, which may interfere with heat dissipation. Thus, in embodiments of the present disclosure, it is provided to substantially increase the thickness of the metal layer between the semiconductor chip and the insulating layer while maintaining the thickness of the heat sink plate.

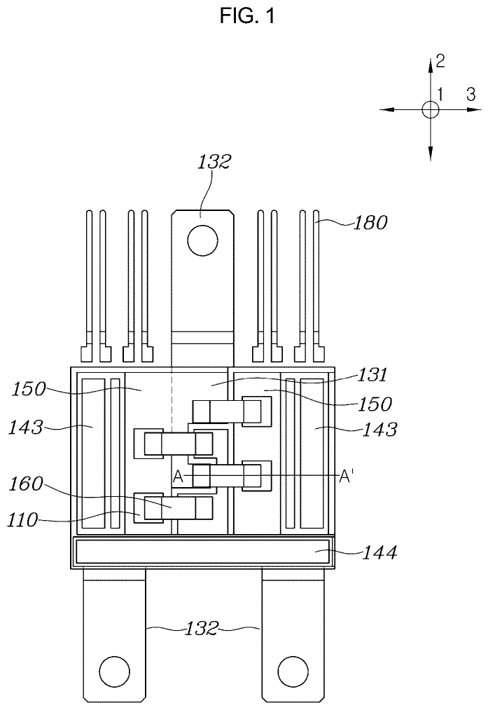

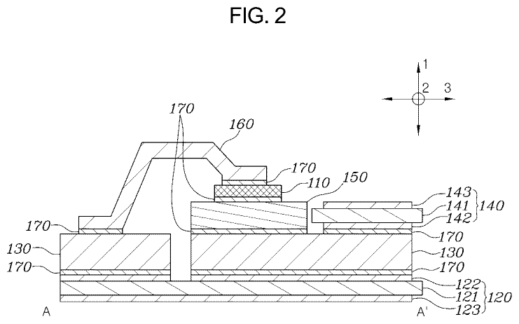

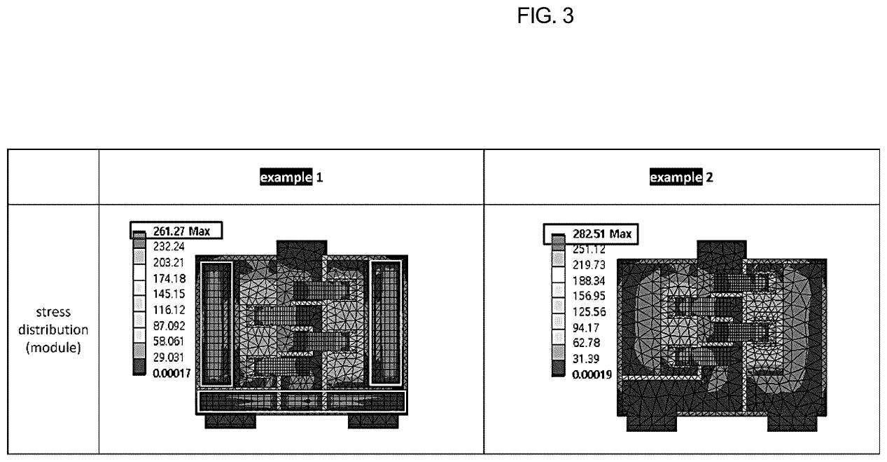

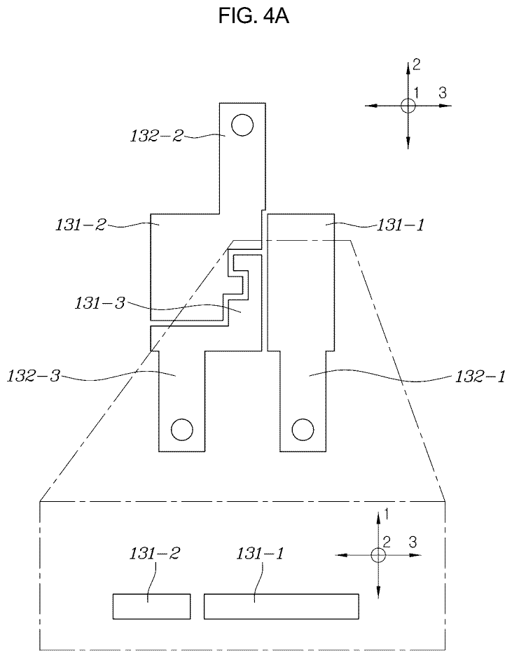

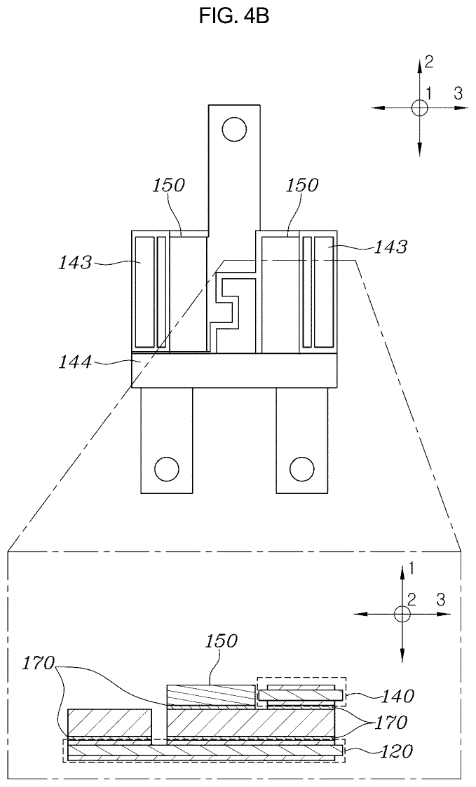

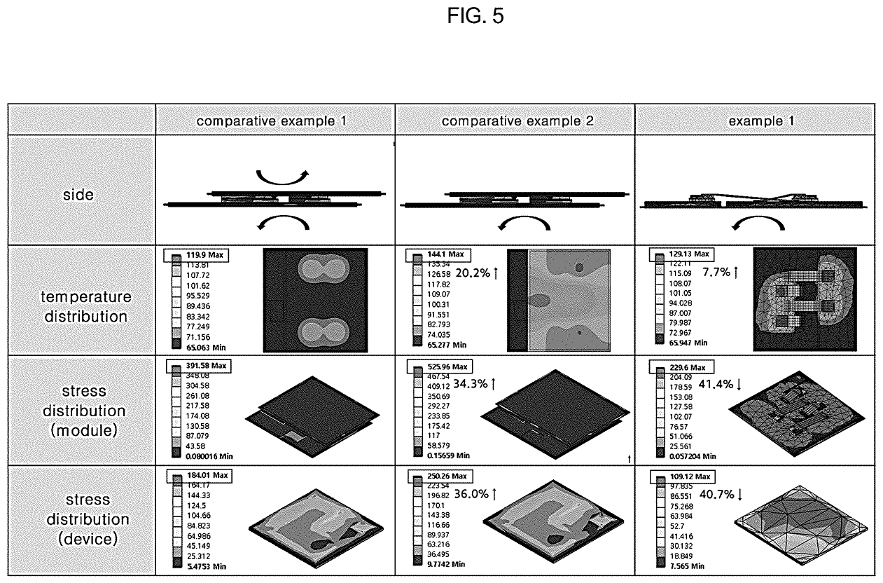

Hereinafter, a configuration of a power module according to the exemplary embodiments of the present disclosure will be described with reference to FIG. 1, FIG. 2, FIG. 3, FIG. 4, and FIG. 5.

First, components and a structure of a power module according to an exemplary embodiment will be described with reference to FIG. 1 and FIG. 2.

FIG. 1 is a plan view of a power module according to an exemplary embodiment of the present disclosure, and FIG. 2 is a cross-sectional view of the power module shown in FIG. 1 taken along line A-A′.

Referring to FIG. 1 and FIG. 2, the power module according to the exemplary embodiment of the present disclosure includes a plurality of semiconductor chips 110, an insulating circuit board 120, and a plurality of lead frames 130, and may further include an additional substrate 140, a second metal layer 150, a connecting portion 160, and a bonding material 170. FIG. 1 and FIG. 2 mainly show the components related to the present disclosure, and an actual power module may be implemented with more or fewer components than the case in the exemplary embodiment of the present disclosure. Hereinafter, each component will be described.

The plurality of semiconductor chips 110 may be turned ON/OFF according to the transfer of a gate voltage, and the semiconductor chips 110 may be, for example, switching elements such as insulated gate bipolar transistors (IGBTs) and metal oxide semiconductor field effect transistors (MOSFETs).

The insulating circuit board 120 includes an insulating layer 121 for blocking electrical connection with the outside. The insulating layer 121 may be implemented with, for example, ceramics such as Si₃N₄.

A first metal layer 122 is disposed on one surface of the insulating layer 121 in the first direction thereof. The first metal layer 122 may be made of, for example, a copper (Cu) material, and an electrical connection structure may be formed by a pattern.

A heat sink plate 123 may be disposed on the other surface of the insulating layer 121 in the first direction thereof. Heat generated from the semiconductor chips 110 is transferred to the heat sink plate 123 via the first metal layer 122 and the insulating layer 121. However, due to the arrangement of the insulating layer 121, the electrical connection between the first metal layer 122 and the insulating layer 121 is blocked. The heat sink plate 123 may release heat transferred through heat exchange with the outside thereof, and may be formed of a copper (Cu) material like the first metal layer 122. As the heat transfer to the heat sink plate 123 is made more efficient, the heat dissipation efficiency is improved so that the operating temperature of the power module may be lowered.

Meanwhile, in the exemplary embodiment shown in FIG. 1, one surface in the first direction of the insulating layer 121 on which the first metal layer 122 is disposed may mean an upper surface of the insulating layer 121, while the other surface in the first direction of the insulating layer 121 on which the heat sink plate 123 is disposed may mean a lower surface of the insulating layer 121.

Meanwhile, when the insulating layer 121 is made of a ceramic material and the first metal layer 122 and the heat sink plate 123 are made of a copper (Cu) material, the insulating circuit board 120 may be implemented as an active metal brazed (AMB) substrate produced by brazing at temperatures of about 1,000 degrees and higher.

In the high-temperature bonding process, warpage may occur due to a difference in coefficients of thermal expansion between the material of the insulating layer 121 and the materials of first metal layers 122 and the heat sink plate 123 disposed on and beneath the insulating layer 121, respectively. Thus, it is common to dispose the first metal layer 122 and the heat sink plate 123 on and beneath the insulating layer 121 with symmetrical thickness or volume. Furthermore, as the thicknesses of the first metal layer 122 and the heat sink plate 123 increase, greater stress is applied to the joints with the insulating layer 121 when the temperature changes, which may prevent perfect bonding. Accordingly, it is difficult to change the thickness of the first metal layer 122 of the insulating circuit board 120. Yet, the thickness of the metal layer disposed between the semiconductor chips 110 and the insulating layer 121 may be substantially increased through the manufacturing process of the power module and the structure of the lead frame 130, which will be described later.

Meanwhile, the plurality of lead frames 130 are disposed between the semiconductor chip 110 and the insulating circuit board 120 in the first direction thereof. The plurality of lead frames 130 may include a first lead frame, a second lead frame, and a third lead frame, and each lead frame 130 may include a terminal portion 132 and an extension portion 131 extending from the terminal portion 132 onto the insulating circuit board 120.

At the present time, the first lead frame and the second lead frame may be disposed to overlap the semiconductor chips 110 on a plane through the extension portions 131-1 and 131-2, respectively, while the third lead frame may be disposed so as not to overlap the semiconductor chips 110 on the plane.

Furthermore, each lead frame 130 may be formed to have a greater thickness than the first metal layer 122 of the insulating circuit board. For example, the thickness of the lead frame 130 may be 0.8 mm or more and the thickness of the first metal layer 122 may be 0.2 mm or less.

As the first metal layer 122 is thinly implemented and the lead frame 130 is thickly implemented, in the manufacturing process of the insulating circuit board 120, the joint stress is alleviated so that durability may be improved since the thickness of the first metal layer 122 is reduced, while during the operation of the power module, the heat transfer efficiency may be improved since the thickness of the entire metal layer that transfers heat generated from the semiconductor chips 110 is increased due to the thickness of the lead frame 130.

As the lead frame 130 according to the exemplary embodiment of the present disclosure is located between the semiconductor chips 110 and the insulating circuit board 120 in the first direction, the lead frame 130 practically serves as a metal layer, and thus the thickness of the metal layer that transfers the heat generated from the semiconductor chips 110 to the heat sink plate 123 may be substantially increased while the thickness of the first metal layer 122 of the insulating circuit board is maintained. Moreover, since the present substantial increase in thickness is irrelevant to the manufacturing process of the insulating circuit board 120, durability problems caused by high-temperature heat treatment during the process may be prevented from occurring. A detailed description of each lead frame 130 will be provided later with reference to FIG. 4A.

Meanwhile, a plurality of second metal layers 150 are located between the semiconductor chips 110 and the lead frame 130 in the first direction, and each second metal layer 150 connects the semiconductor chips 110 and the first lead frame and the semiconductor chips 110 and the second lead frame, respectively.

To be specific, the second metal layers 150 are located between the first lead frame and at least some of the semiconductor chips overlapping the first lead frame on the plane, and between the second lead frame and the rest of the semiconductor chips overlapping the second lead frame on the plane, respectively.

Furthermore, the second metal layer 150 may be made of a material having a coefficient of thermal expansion greater than that of the semiconductor chip 110 and smaller than that of the lead frame 130, and may be made of, for example, a Mo—Cu alloy material. Because of such characteristics of the second metal layer 150, stress due to a difference in coefficients of thermal expansion between the semiconductor chip 110 and the lead frame 130 is relieved, and the bonding durability between the respective components may be improved.

Furthermore, the second metal layer 150 may have a larger planar area than the semiconductor chip 110 so that heat generated from the semiconductor chips 110 are diffused in a wider range in the second and third directions to be efficiently transferred to the heat sink plate 123.

Meanwhile, a plurality of additional substrates 140 may be disposed on top of the lead frame 130 to overlap a portion of the edge portion of the insulating circuit board 120 without overlapping with the semiconductor chips 110 on the plane.

The additional substrates 140 may be disposed to be symmetrical to the insulating circuit board 120 with respect to the lead frames 130 in the first direction thereof. Thus, the thickness and material of the additional substrate 140 may be the same as those of the insulating circuit board 120, and the respective first metal layers of the additional substrate 140 and the insulating circuit board 120 may be disposed to face each other.

Meanwhile, the plurality of additional substrates 140 may include a first additional substrate and a second additional substrate. This will be explained below.

The plurality of additional substrates 140 according to the exemplary embodiment of the present disclosure may include the first additional substrate disposed each on top of the first lead frame and the second lead frame in the first direction and configured to transfer an input gate voltage from a signal pin 180 to at least some of the semiconductor chips 110. The first additional substrates 143 may extend in the second direction as shown in FIG. 2 and may be electrically connected to the semiconductor chips 110 to transfer a gate voltage. In the instant case, the semiconductor chips 110 and the first additional substrates 143 may be connected by wire bonding or the like.

Furthermore, the plurality of additional substrates 140 may include the second additional substrate 144 disposed on top of at least two of the lead frames 130 to connect the at least two of the lead frames to each other. By the second additional substrate 144, the lead frames 130 separated into a plurality may be fixed. As shown in FIG. 1, the second additional substrate 144 extends in the third direction and is disposed on top of the different lead frames 130 to fix both.

Changes in stress distribution following the arrangement of the additional substrate 140 will be described with reference to FIG. 3 hereinafter.

FIG. 3 is a view showing stress distributions in the power module following an arrangement of the additional substrate 140 according to the exemplary embodiment of the present disclosure.

Referring to FIG. 3, the stress distribution analysis results in the module of Example 1 in which the additional substrates 140 are disposed and Example 2 in which the additional substrates 140 are not disposed are shown. In the case of Example 1, it may be confirmed that the additional substrates 140 distribute the stress inside the module, so that the maximum stress in the module is 7.5% smaller than in Example 2.

Hereinafter, the manufacturing process of the power module according to the exemplary embodiment of the present disclosure will be described with reference to FIG. 4A and FIG. 4B based on the structure of the power module according to the above-described embodiments.

FIG. 4A and FIG. 4B are views showing the manufacturing process of the power module according to the exemplary embodiment of the present disclosure. FIG. 4A shows a plurality of lead frames 130, and FIG. 4B shows a state in which the additional substrate 140, the second metal layer 150, and the insulating circuit board 120 are stacked on top and under the plurality of lead frames 130.

A manufacturing method of a power module according to various exemplary embodiments of the present disclosure may include: preparing a plurality of semiconductor chips 110, an insulating circuit board 120, a plurality of lead frames 130, and a plurality of second metal layers 150; stacking and bonding the plurality of lead frames 130 on the insulating circuit board 120; stacking and bonding the plurality of second metal layers on top of some of the lead frames 130 overlapping the semiconductor chips 110 on the plane; and stacking and bonding the plurality of semiconductor chips 110 on top of the plurality of second metal layers 150.

Prior to a detailed description of the manufacturing process, a planar structure of the lead frame 130 according to the exemplary embodiment of the present disclosure will be first described with reference to FIG. 4A.

Referring to FIG. 4A, the first lead frame includes: a first terminal portion 132-1; and a first extension portion 131-1 extending from the first terminal portion 132-1 onto the insulating circuit board 120 to overlap at least some of the plurality of semiconductor chips 110 on a plane.

The second lead frame includes: a second terminal portion 132-2; and a second extension portion 131-2 extending from the second terminal portion 132-2 onto the insulating circuit board 120 to overlap the rest of the plurality of semiconductor chips 110 on a plane.

That is, the plurality of semiconductor chips 110 are distributed and disposed on the first lead frame and the second lead frame.

Meanwhile, the third lead frame includes: a third terminal portion 132-3; and a third extension portion 131-3 extending from the third terminal portion 132-3 to be located between the first lead frame and the second lead frame without overlapping with the semiconductor chip 110 on the plane.

At the present time, the terminal portion 132 may perform functions of a (+) terminal, a (−) terminal, and an output terminal.

Hereinafter, the manufacturing method of the power module according to the exemplary embodiment of the present disclosure will be described in detail based on the configuration of the lead frame 130 described above.

Referring to FIG. 4B, the plurality of lead frames 130 shown in FIG. 4A may be stacked on the insulating circuit board 120 and bonded with the bonding material 170.

In the instant case, the metal bonding material 170 is applied to a region where the insulating circuit board 120 and the plurality of lead frames 130 overlap on the plane, and face-to-face bonding may be achieved through pressurization and heat treatment (i.e., sintering). At the instant time, the metal bonding material 170 may be, for example, Ag paste.

Meanwhile, unlike the above, the insulating circuit board 120 and the lead frame 130 may be joined by soldering.

Thereafter, the plurality of second metal layers are stacked on top of the lead frames 130 overlapping the semiconductor chips 110 on a plane, that is, the first lead frame and the second lead frame, among the lead frames 130, and may be joined by the above-described sintering or soldering.

Furthermore, the manufacturing method of a power module according to the exemplary embodiment of the present disclosure may further include: stacking and bonding a plurality of substrates 140 provided separately on a region of the lead frames 130 that does not overlap with the semiconductor chips 110 but overlaps with a portion of an edge portion of the insulating circuit board 120 on the plane.

The semiconductor chips 110 may be stacked and bonded on top of the second metal layers as shown in FIG. 1 and FIG. 2, and the bonding here may be performed through sintering or soldering, as described above.

After the semiconductor chips 110 are stacked and bonded, a step of connecting any one of the semiconductor chips 110 and one of the lead frames 130 that do not overlap with the any one of the semiconductor chips 110 on the plane with one of the connecting portions 160 provided separately may be followed. At the instant time, connection between the semiconductor chips 110 and the lead frames 130 may be performed through, for example, wire bonding or clip bonding.

Hereinafter, effects of the power module according to the exemplary embodiment of the present disclosure will be described by comparing with comparative examples with reference to FIG. 5.

FIG. 5 is a view showing effects of the power module according to the exemplary embodiment of the present disclosure.

Referring to FIG. 5, a table for comparing the temperature distributions and stress distributions of Comparative Example 1 and Comparative Example 2 corresponding to conventional power modules and the power module according to the exemplary embodiment of the present disclosure (referred to as ‘Example 1’ for convenience) under the same heating and cooling water temperature conditions is shown.

The power modules according to Comparative Example 1 and Comparative Example 2 have the same laminated structure, but there is a difference in that the power module of Comparative Example 1 is under double-sided cooling condition in which the top portion and bottom portion are simultaneously cooled, whereas the power module of Comparative Example 2 is under single-sided cooling condition in which only the bottom is cooled.

Example 1 assumes a structure in which an AMB insulating circuit board 120, a lead frame 130 made of Cu material having a thickness of 0.8 mm, a second metal layer 150 made of a Mo—Cu alloy material having a thickness of 0.5 mm, and a SiC semiconductor chip 110 are sequentially stacked.

Furthermore, it is assumed that a 0.3 mm thick Cu clip is applied to the top portion of the SiC semiconductor chip 110 to conduct current, each joint reflects Ag sintered bonding material 170 having a thickness of 0.025 mm, and single-sided cooling condition realized by water cooling is applied on the lower surface.

As a result of the temperature distribution analysis, in the case of Example 1 under the double-sided cooling condition, it can be seen that the maximum temperature in the module is 129.1° C., which is 9.2° C. higher than that of Comparative Example 1 (i.e., 7.7% increase). However, it can be seen that the heat dissipation effect of Example 1 is superior to that of Comparative Example 2, in which the maximum temperature is 24.2° C. higher than that of Comparative Example 1 (i.e., 20.2% increase). Thus, it can be said that Example 1 has efficient heat dissipation performance under a same single-sided cooling condition.

Moreover, in the case of stress applied to the power module and the semiconductor chips 110, it can be seen that the power module according to the exemplary embodiment of the present disclosure is advantageous in terms of durability as the stress is reduced by 40% or more compared to the double-sided cooling power module of Comparative Example 1.

According to the exemplary embodiments of the present disclosure as described above, by increasing the thickness of an entire metal layer disposed under a semiconductor chip by an insulating circuit board and a lead frame, thermal conductivity may be enhanced to improve heat diffusion and dissipation performance, lowering the operating temperature of a power module.

Furthermore, by disposing a second metal layer and an additional substrate on top of the lead frame, it is possible to ensure the durability of the power module by dispersing thermal stress generated by the changes in temperature during process and operation.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described to explain certain principles of the present disclosure and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A power module, comprising:
semiconductor chips;
an insulating circuit board including an insulating layer and a first metal layer disposed on a first surface of the insulating layer; and
lead frames disposed between the semiconductor chips and the insulating circuit board,
wherein the lead frames include:
a first lead frame including a first terminal portion and a first extension portion extending from the first terminal portion onto the insulating circuit board to overlap with a predetermined number of the semiconductor chips on a plane; and
a second lead frame including a second terminal portion and a second extension portion extending from the second terminal portion onto the insulating circuit board to overlap with a remaining number of the semiconductor chips on the plane.

2. The power module of claim 1, further including:
second metal layers respectively connecting the predetermined number of the semiconductor chips and the first lead frame, and the remaining number of the semiconductor chips and the second lead frame.

3. The power module of claim 2, wherein a thermal expansion coefficient of each of the second metal layers is greater than a thermal expansion coefficient of each of the semiconductor chips and smaller than a thermal expansion coefficient of each of the lead frames.

4. The power module of claim 2, wherein each of the second metal layers has a larger planar area than each of the semiconductor chips.

5. The power module of claim 1, wherein each of the lead frames has a thickness greater than a thickness of the first metal layer.

6. The power module of claim 1, wherein the lead frames further include:
a third lead frame including a third terminal portion and a third extension portion extending from the third terminal portion to be located between the first lead frame and the second lead frame without overlapping with the semiconductor chips on the plane.

7. The power module of claim 6, further including:
additional substrates disposed on the lead frames so as not to overlap with the semiconductor chips while overlapping with a portion of an edge portion of the insulating circuit board on the plane.

8. The power module of claim 7, further including:
a signal pin configured to receive a voltage from outside thereof,
wherein the additional substrates include first additional substrates, each of which is disposed on the first lead frame and the second lead frame, respectively, and configured to transfer a voltage input from the signal pin to at least one of the semiconductor chips.

9. The power module of claim 7, wherein the additional substrates include a second additional substrate disposed on at least two of the lead frames, and configured to connect the at least two of the lead frames to be fixed each other.

10. The power module of claim 7, wherein the additional substrates are disposed to be vertically symmetrical with the insulating circuit board based on the lead frames.

11. The power module of claim 1, wherein the insulating circuit board further includes a heat sink plate disposed on a second surface opposite to the first surface of the insulating layer.

12. A manufacturing method of a power module, the method comprising:
preparing semiconductor chips, an insulating circuit board, lead frames, and second metal layers;
stacking and bonding the lead frames on the insulating circuit board;
stacking and bonding the second metal layers on some of the lead frames overlapping with the semiconductor chips on a plane; and
stacking and bonding the semiconductor chips on the second metal layers.

13. The manufacturing method of claim 12, wherein the stacking and bonding the lead frames includes applying a metal bonding material to a region where the insulating circuit board and the lead frames overlap on the plane, and face-to-face bonding through pressurization and heat treatment.

14. The manufacturing method of claim 12, wherein the preparing includes preparing additional substrates, and further includes stacking and bonding the additional substrates on a region of the lead frames that does not overlap with the semiconductor chips but overlaps with a portion of an edge portion of the insulating circuit on the plane.

15. The manufacturing method of claim 12, wherein the preparing includes preparing connecting portions, and further includes connecting any one of the semiconductor chips and one of the lead frames that do not overlap with the any one of the semiconductor chips on the plane with one of the connecting portions.

16. The manufacturing method of claim 12,
wherein the insulating circuit board includes an insulating layer, a first metal layer disposed on a first surface of the insulating layer, and a heat sink plate disposed on a second surface opposite to the first surface of the insulating layer, and
wherein when the insulating layer is made of a ceramic material and the first metal layer and the heat sink plate are made of a copper (Cu) material, the insulating circuit board is implemented as an active metal brazed (AMB) substrate produced by brazing at temperatures of about 1,000 degrees and higher than 1,000 degrees.
